(19) United States
(12) Patent Application Publication
(10) Pub. No.: US 2023/0245858 A1
(43) Pub. Date: Aug. 3, 2023

(54) SUBSTRATE PROCESSING APPARATUS AND METHOD FOR PROCESSING SUBSTRATE

(71) Applicant: Tokyo Electron Limited, Tokyo (JP)

(72) Inventors: Hitoshi KATO, Iwate (JP); Hiroyuki KIKUCHI, Iwate (JP)

(21) Appl. No.: 18/159,865

(22) Filed: Jan. 26, 2023

(30) Foreign Application Priority Data
Feb. 2, 2022 (JP) 2022-014699

(51) Int. Cl. H01J 37/32; C23C 16/455

(52) U.S. Cl. CPC H01J 37/32357; H01J 37/32449; H01J 37/32715; C23C 16/45544; H01J 2237/3321

(57) ABSTRACT

A substrate processing apparatus includes a processing chamber, a substrate support, and a plasma source configured to generate an electric field in a plasma processing region between a surface facing the substrate support and the substrate support. The substrate processing apparatus includes process gas nozzles via which a gas is delivered to the plasma processing region. The process gas nozzles includes a gas mixture nozzle via which a gas mixture of additive gas and a noble gas for forming the plasma is delivered. The process gas nozzles includes a noble gas nozzle via which the noble gas, which is not mixed with the additive gas, is delivered to flow along the facing surface. The noble gas nozzle is provided at a location closer to the facing surface than the gas mixture nozzle is.

### CROSS-REFERENCE TO RELATED APPLICATIONS

This patent application claims priority to Japanese Patent Application No. 2022-014699, filed Feb. 2, 2022, the contents of which are incorporated herein by reference in their entirety.

### TECHNICAL FIELD

The present disclosure relates to a substrate processing apparatus and a method for processing a substrate.

### BACKGROUND

Patent Document 1 discloses a substrate processing apparatus that performs a deposition process by forming a plasma in a processing chamber. The substrate processing apparatus supplies argon (Ar) that is a plasma gas to a plasma processing region, while supplying an additive gas, such as oxygen (O₂), hydrogen (H₂), nitrogen (N₂), and ammonia (NH₃), to the plasma processing region to improve film quality. A portion of the processing chamber where radio frequency power is output to the plasma processing region is formed of quartz.

Although a quartz portion of the processing chamber is physically bombarded with an Ar plasma, the quartz portion is not appreciably damaged by the physical bombardment. However, when the additive gas is added to the Ar plasma, the Ar plasma chemically reacts with the additive gas, and thus the quartz portion may be further damaged.

### RELATED-ART DOCUMENT

### Patent Document

[Patent Document 1] Japanese Unexamined Patent Application Publication No. 2015-220293

### SUMMARY

One aspect of the present disclosure relates to a substrate processing apparatus. The substrate processing apparatus includes a processing chamber configured to process a substrate. The substrate processing apparatus includes a substrate support provided in the processing chamber and configured to support a substrate. The substrate processing apparatus includes a plasma source configured to generate an electric field in a plasma processing region between a surface facing the substrate support and the substrate support, the electric field causing formation of a plasma. The substrate processing apparatus includes process gas nozzles via which a gas is delivered to the plasma processing region. The process gas nozzles include a gas mixture nozzle via which a gas mixture of an additive gas and a noble gas for forming the plasma is delivered. The process gas nozzles include a noble gas nozzle via which the noble gas, which is not mixed with the additive gas, is delivered along the facing surface, the noble gas nozzle being provided at a location closer to the facing surface than the gas mixture nozzle is.

### BRIEF DESCRIPTION OF THE DRAWINGS

FIG. 1 is a schematic cross-sectional view of a configuration example of a substrate processing apparatus according to a first embodiment.

FIG. 2 is a schematic plan view of the substrate processing apparatus in FIG. 1.

FIG. 3 is a schematic cross-sectional view of the configuration of the substrate processing apparatus that includes a plasma processing region.

FIG. 4 is an enlarged schematic cross-sectional view of the substrate processing apparatus taken along line IV-IV in FIG. 3.

FIG. 5 is a schematic plan view of the plasma processing region in the substrate processing apparatus according to the first embodiment.

FIG. 6 is a flowchart illustrating an example of a method for processing a substrate.

FIG. 7 is a graph illustrating a deposited amount of quartz in a test in which plasma processing was performed in the substrate processing apparatus.

FIG. 8 is a schematic plan view of the plasma processing region of the substrate processing apparatus according to a second embodiment.

### DETAILED DESCRIPTION

One or more embodiments are described below with reference to the drawings. In the drawings, the same components are denoted by the same numerals, and accordingly, redundant description thereof may be omitted.

### First Embodiment

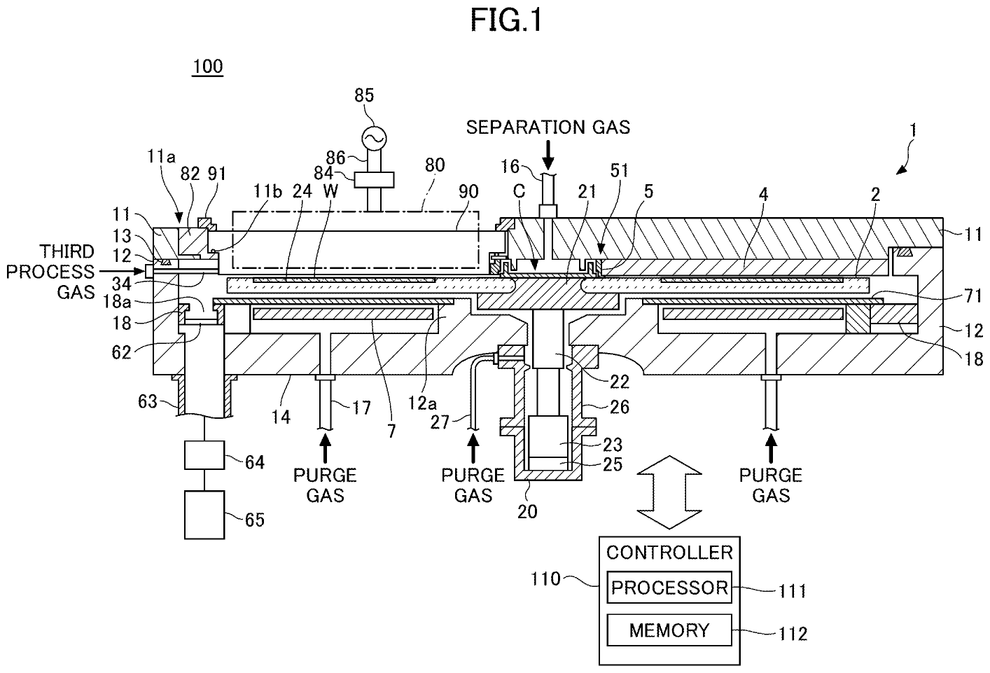

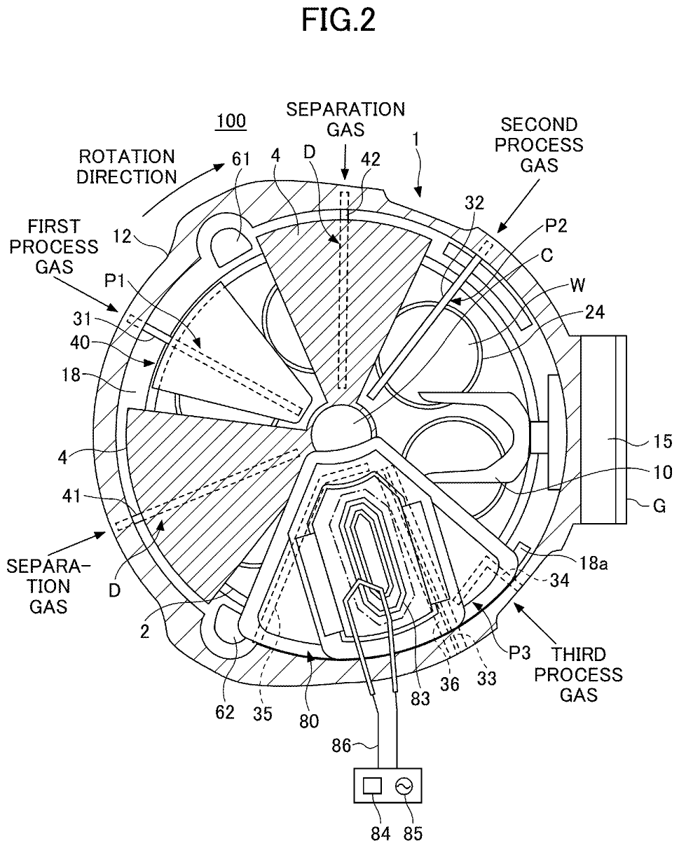

FIG. 1 is a schematic cross-sectional view of a configuration example of a substrate processing apparatus 100 according to the first embodiment. FIG. 2 is a schematic plan view of the substrate processing apparatus in FIG. 1. In FIG. 2, a top plate is not illustrated for convenience of explanation. As illustrated in FIGS. 1 and 2, the substrate processing apparatus 100 according to the first embodiment is a film deposition apparatus that forms a predetermined film on the surface of a substrate. The substrate processing apparatus 100 performs a deposition process by atomic layer deposition (ALD) or molecular layer deposition (MLD) that is enabled in substrate processing.

As the substrate used in the deposition process, a semiconductor wafer such as a silicon semiconductor, a compound semiconductor, or an oxide semiconductor is used (hereinafter, the substrate is also referred to as a wafer W). The wafer W may have a recessed pattern such as a trench or a via. A type of film that is deposited on the wafer W is not particularly limiting. In the following description, a case where a silicon oxide (SiO₂) film is formed will be described below in detail.

As illustrated in FIG. 1, the substrate processing apparatus 100 includes a substantially cylindrical processing chamber 1 and a rotary table 2 (substrate support) that rotates (revolves) one or more wafers W in the processing chamber 1. The substrate processing apparatus 100 also includes a controller 110 that controls each component of the substrate processing apparatus 100.

The processing chamber 1 accommodates wafers W therein, and allows a SiO₂ film to be formed on each wafer W. The processing chamber 1 includes a top plate 11 and a chamber body 12. A processing compartment is provided in an interior of the processing chamber 1. In the processing compartment, the wafers W are accommodated and a predetermined film is formed on each wafer W. The processing chamber 1 includes an annular sealing member 13 at the upper surface of an outer peripheral wall of the chamber body 12. The top plate 11 is detachably coupled to the chamber body 12 such that the processing chamber 1 can be hermetically sealed. It is sufficient when the diameter (inner diameter) of the processing chamber 1 is designed to be, for example, about 1100 mm in a plan view.

A separation-gas supply tube 16 via which a separation gas is supplied is coupled to a central portion of the top plate 11. Purge-gas supply tubes 17 via which a purge gas such as Ar gas is supplied are coupled to a bottom 14 of the chamber body 12. The purge-gas supply tubes 17 are provided along a circumferential direction of the bottom 14. The bottom 14 has an annular protruding portion 12a at a location close to the outer peripheral surface of a core 21 to which the rotary table 2 is secured.

As illustrated in FIG. 2, the processing chamber 1 includes a loading port 15 via which a given wafer W is transferred between the rotary table 2 and a transfer arm 10, and includes a gate valve G for opening and closing the loading port 15. The gate valve G hermetically seals the processing compartment of the processing chamber 1, while the loading port 15 is closed. When the rotary table 2 causes a given recess 24 in which the wafer W is placed to be located near the loading port 15, the wafer W is transferred between the rotary table 2 and the transfer arm 10.

As illustrated in FIG. 1, the central portion of the rotary table 2 is secured to the core 21 that is substantially cylindrical. The core 21 is coupled to a rotating shaft 22 that extends vertically, and the rotating shaft 22 is supported by a drive unit 23. The drive unit 23 rotates the rotary table 2 about a vertical axis (clockwise in FIG. 2). The diameter of the rotary table 2 is not particularly limiting. For example, it is sufficient when the diameter of the rotary table 2 is set to about 1000 mm, in a case where the diameter of the processing chamber 1 is 1100 mm.

The drive unit 23 includes an encoder 25 that detects a rotation angle of the rotating shaft 22. The rotation angle of the rotating shaft 22, detected by the encoder 25, is transmitted to the controller 110, and the controller 110 uses the rotation angle to specify a position of the wafer W that is placed in each recess 24 in the rotary table 2.

A lower end of the rotating shaft 22, the drive unit 23, and the encoder 25 are accommodated in a case 26. The case 26 is hermetically attached to the bottom 14 of the processing chamber 1. A purge-gas supply tube 27 via which purge gas is supplied to a region below the rotary table 2 is coupled to the case 26.

The surface of the rotary table 2 has, for example, a plurality of (in the present embodiment, six) recesses 24 that are each circular, and the wafer W having a diameter of 300 mm can be placed in a corresponding recess 24. The recesses 24 are arranged at regular intervals in a rotation direction (clockwise in FIG. 2) of the rotary table 2. Each recess 24 has an internal diameter that is slightly greater (about 1 mm to about 4 mm) than the diameter of the wafer W. The depth of each recess 24 is substantially the same as the thickness of the wafer W, or is greater than the thickness of the wafer W. With this arrangement, in a state where the wafer W is accommodated in a given recess 24, the surface of the wafer W and the surface of the rotary table 2 become on the same level, or the surface of the wafer W becomes lower than the surface of the rotary table 2.

A plurality of (for example, three) through-holes (not illustrated) through which respective lifter pins, not illustrated, pass are formed at the bottom surface of each recess 24. Each lifter pin is provided at a location proximal to the loading port 15, where the wafer W is loaded and unloaded. The lifter pins are vertically raised and lowered by an elevating mechanism not illustrated.

As illustrated in FIG. 2, in the substrate processing apparatus 100, gas nozzles are disposed above a region where the recesses 24 pass. Each gas nozzle extends in a direction normal to the rotation direction of the rotary table 2, and the gas nozzles are arranged at intervals in a circumferential direction of the processing chamber 1. In the present embodiment, the gas nozzles include a first process gas nozzle 31, a second process gas nozzle 32, third process gas nozzles 33 to 36, and separation gas nozzles 41 and 42.

The first process gas nozzle 31, the second process gas nozzle 32, the third process gas nozzles 33 to 36, and the separation gas nozzles 41 and 42 are disposed in the processing compartment between the rotary table 2 and the top plate 11. Each of the first process gas nozzle 31, the second process gas nozzle 32, and the separation gas nozzles 41 and 42 extends linearly in a radial direction that is from the outer peripheral wall of the processing chamber 1 toward a central region C. Also, these gas nozzles are each fixed to be parallel (horizontally) to the rotary table 2. In FIG. 2, the third process gas nozzles 33 to 36, the separation gas nozzle 41, the first process gas nozzle 31, the separation gas nozzle 42, and the second process gas nozzle 32 are arranged in this order with respect to the clockwise direction from the loading port 15.

The first process gas nozzle 31 has gas holes, not illustrated, in a lower side (side facing the rotary table 2), and first process gas is delivered, through the gas holes, to a first processing region P1 that is situated on a lower side of the processing compartment. The first process gas nozzle 31 is coupled to a first process-gas supply via a flow control valve (not illustrated) or an opening-and-closing valve (not illustrated), outside the processing chamber 1. When a SiO₂ film is formed, a silicon-containing gas that is a first process gas is delivered onto the wafer W via the first process gas nozzle 31, for example.

A nozzle cover 40 is partially provided above the first process gas nozzle 31. The nozzle cover 40 covers a top and lateral sides of the first process gas nozzle 31. The nozzle cover 40 guides the first process gas to flow along the wafer W. Also, the nozzle cover 40 guides separation gas to flow toward the top plate 11 of the processing chamber 1, while preventing the separation gas from flowing toward the wafer W.

The lower side (side facing the rotary table 2) of the second process gas nozzle 32 has gas holes, and a second process gas is delivered, through the gas holes, to a second processing region P2 on the lower side of the processing compartment. The second process gas nozzle 32 is coupled to a second process gas supply (not illustrated) via a flow control valve (not illustrated) or an opening-and-closing valve (not illustrated), outside the processing chamber 1. When the SiO₂ film is formed, oxidization gas (O₂, O₃, a gas mixture of O₂ and O₃, or the like) that is the second process gas is delivered via the second process gas nozzle 32.

Third process gas is delivered into a third processing region P3 of the processing compartment via the third process gas nozzles 33 to 36. The third processing region P3 is a region in which plasma processing is enabled with respect to the wafer W. In the following, the third processing region P3 is also referred to as a plasma processing region P3. A structure provided in the plasma processing region P3 will be described in detail later.

The separation gas nozzle 41 defines a separation region D1 that divides the first processing region P1 and the second processing region P2. Also, the separation gas nozzle 41 defines a separation region D2 that divides the third processing region P3 and the first processing region P1. The lower side (side facing the rotary table 2) of each of the separation gas nozzles 41 and 42 has gas holes, and a separation gas, such as an inert gas or a noble gas, is delivered, through the gas holes, to a corresponding separation region among the separation regions D1 and D2. Each of the separation gas nozzles 41 and 42 is coupled to a separation gas supply (not illustrated) via a flow control valve (not illustrated) or an opening-and-closing valve (not illustrated), outside the processing chamber 1.

In the respective separation regions D1 and D2, protruding portions 4 each having a substantially fan shape are provided on the bottom surface of the top plate 11 (see FIG. 1) in the processing chamber 1. Each protruding portion 4 has a groove (not illustrated) that extends radially at a circumferential center of the protruding portion 4. The separation gas nozzles 41 and 42 are each accommodated in a corresponding groove.

Referring back to FIG. 1, a protruding portion 5 is provided on a central portion of the bottom surface of the top plate 11. The protruding portion 5 has a substantially annular shape that is circumferentially continuously formed to correspond to the protruding portion 4 toward the central region C. The lower surface of the protruding portion 5 is formed at the same level as the lower surface of the protruding portion 4. In order to reduce mixing of gases in the central region C, a labyrinth structure 51 is provided above the core 21 so as to be toward the rotation axis of the rotary table 2 with respect to the protruding portion 5.

As illustrated in FIGS. 1 and 2, the processing chamber 1 includes an annular side ring 18 that is a cover, and the side ring 18 is located outside and below the rotary table 2. A groove-shaped gas flow path 18a through which the gas can flow is formed within the side ring 18.

The top surface of the side ring 18 includes a first exhaust port 61 and a second exhaust port 62. The first exhaust port 61 is formed between the first process gas nozzle 31 and the separation region D1. The second exhaust port 62 is formed between the plasma processing region P3 and the separation region D2. The first exhaust port 61 is used to mainly exhaust the first process gas or the separation gas, and the second exhaust port 62 is used to mainly exhaust the third process gas or the separation gas. As illustrated in FIG. 1, an exhaust tube 63 is coupled to the gas flow path 18a via an exhaust port that is situated at the bottom 14 of the processing chamber 1. A pressure regulator 64 such as a butterfly valve, and a vacuum-exhausting mechanism 65 such as a vacuum pump are coupled to the exhaust tube 63.

The substrate processing apparatus 100 also includes a heater unit 7 in a space between the bottom 14 of the processing chamber 1 and the rotary table 2. The heater unit 7 is accommodated in the cover 71 that is supported by the protruding portion 12a of the chamber body 12. The heater unit 7 heats each wafer W on the rotary table 2, for example, at a temperature ranging from a room temperature to about 700° C.

The controller 110 of the substrate processing apparatus 100 may be implemented by a control computer that includes one or more processors 111, a memory 112, an input-and-output interface (not illustrated), an electronic circuit (not illustrated), and the like. Each processor 111 includes one or more among a central processing unit (CPU), a graphics processing unit (GPU), an application specific integrated circuit (ASIC), a field-programmable gate array (FPGA), a circuit including discrete semiconductors, and the like. The memory 112 may include a volatile memory, a non-volatile memory (which includes, for example, one or more among a compact disc, a digital versatile disc (DVD), a hard disc, a flash memory, and the like). The memory 112 stores a program that causes the substrate processing apparatus 100 to operate, as well as storing a recipe such as a deposition process condition.

Hereinafter, the configuration of the substrate processing apparatus 100 in the plasma processing region P3 will be described. As illustrated in FIG. 2, the substrate processing apparatus 100 includes a plasma source 80 above the plasma processing region P3. The plasma source 80 is formed to have a substantially rectangular shape, in a plan view, with a long side that is situated along the radial direction of the rotary table 2. The plasma source 80 is provided so as to cover a diameter-spanning portion of a given recess 24 (wafer W) that is located in the rotary table 2.

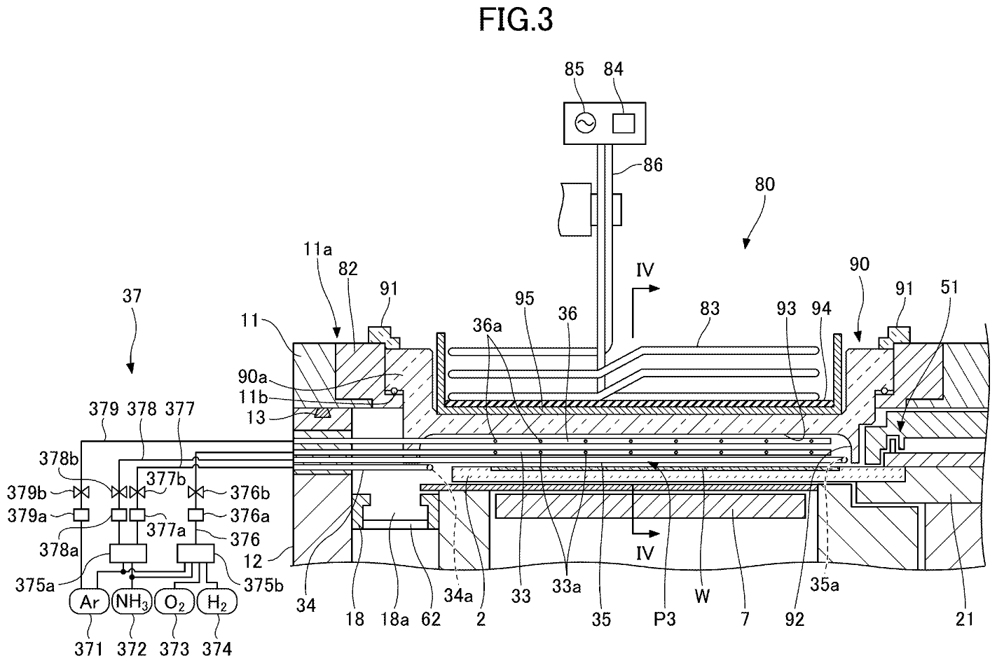

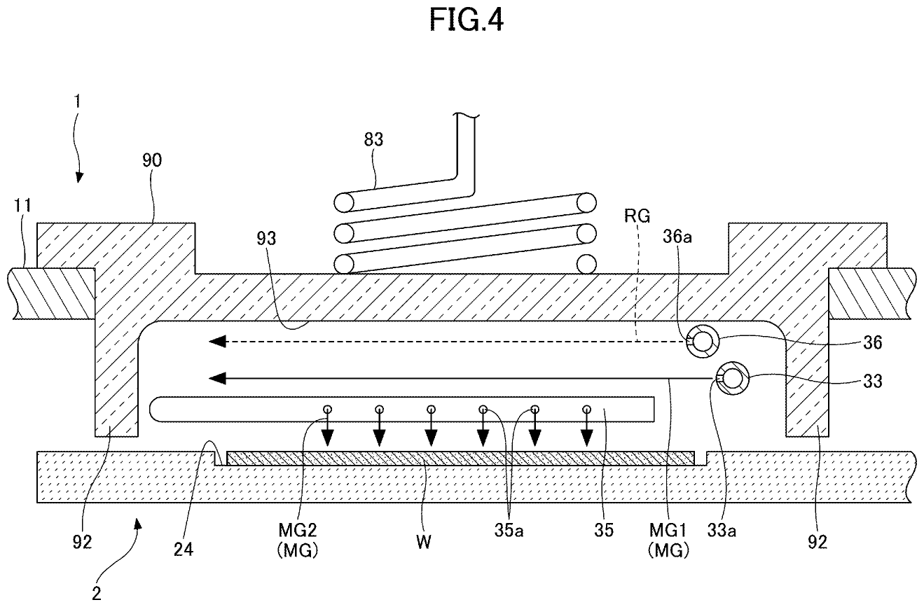

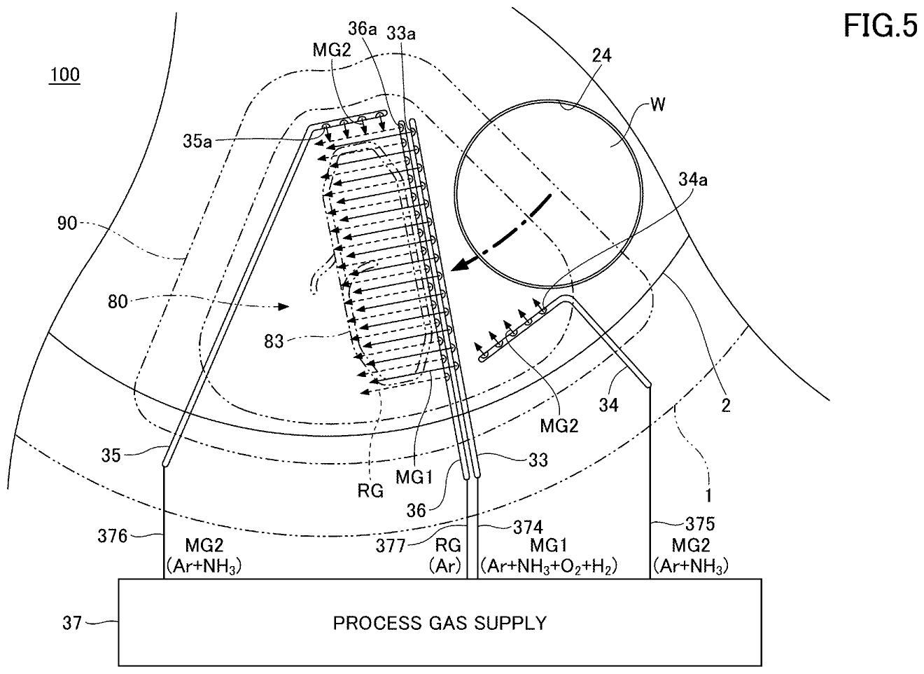

FIG. 3 is a schematic cross-sectional view of the configuration of the substrate processing apparatus 100 with the plasma processing region P3. FIG. 4 is an enlarged schematic cross-sectional view of the substrate processing apparatus 100 taken along the IV-IV line in FIG. 3. FIG. 5 is a schematic plan view of the plasma processing region P3 in the substrate processing apparatus 100 according to the first embodiment. In FIG. 5, for easy understanding of the drawing, the third process gas nozzles 33 to 36 are indicated by solid lines, and components of the processing chamber 1 and the plasma source 80 are indicated by virtual lines (dashed-two dotted lines).

As illustrated in FIGS. 3 and 4, the substrate processing apparatus 100 is an inductively coupled apparatus in which a plasma is formed from a third process gas that is delivered, via the third process gas nozzles 33 to 36, to the processing compartment (plasma processing region P3) by outputting a radio frequency wave from above the processing chamber 1. With this arrangement, the plasma source 80 includes an antenna 83 via which electric fields are applied to the plasma processing region P3, and the antenna 83 is provided on and above the processing chamber 1.

The antenna 83 is disposed so as to hermetically close an interior space of the processing chamber 1. In a plan view (see FIG. 2), the antenna 83 is in the form of a flat coil that corresponds to the rectangular shape of the plasma source 80. As an example, the antenna 83 is formed by winding a metal wire or the like around a vertical axis a plurality of times (for example, three times).

The antenna 83 is coupled to a radio frequency (RF) power source 85 via a matching device 84, outside the processing chamber 1. The RF power source 85 outputs, for example, radio frequency power at a frequency of 13.56 MHz to the antenna 83. The plasma source 80 includes a connection electrode 86 via which the antenna 83 is electrically connected to the matching device 84 and the RF power source 85. The antenna 83 may include (i) a vertically bendable structure, (ii) a vertically movable mechanism that enables the antenna 83 to be automatically vertically bent, (iii) a mechanism that enables a central portion of the rotary table 2 to be automatically moved vertically, or (iv) the like, as needed.

An opening 11a that has a substantially fan shape in a plan view is formed in the top plate 11 that is situated above the third process gas nozzles 33 to 35. In the plasma source 80, a housing 90 that accommodates the antenna 83 is provided via an annular member 82, which encircles an edge of the opening 11a of the top plate 11. A sealing member 11b such as an O-ring is provided between the annular member 82 and the housing 90. In addition, in a state where the annular member 82 and the housing 90 are inserted within the opening 11a, the plasma source 80 is attached to the processing chamber 1 by fixing a frame-shaped pressing member 91 to the top plate 11 with one or more fastening portions such as bolts, and the pressing member 91 is provided along the boundary between the annular member 82 and the housing 90. With this arrangement, the top side of the plasma processing region P3 is hermetically closed.

The housing 90 is formed by a dielectric material such as quartz, and the antenna 83 is located below the top plate 11. The upper periphery of the housing 90 includes a circumferential flange 90a that protrudes upwardly. The central portion of the housing 90 is formed to have a recessed box shape in cross section, and the box shape is recessed toward an inner region of the processing chamber 1. When a given wafer W is located below the housing 90, the housing 90 is disposed so as to cover the wafer W in the radial direction of the rotary table 2. A lower surface of the housing 90 is a surface 93 (hereinafter referred to as a facing surface 93) that faces the rotary table 2 in the plasma processing region P3.

A Faraday shield 95 and an insulating plate 94 are stacked on an opposite side of the facing surface 93 in the housing 90. The Faraday shield 95 is formed by a conductive plate (metal plate). The insulating plate 94 ensures insulation between the Faraday shield 95 and the antenna 83, and is made of quartz or the like.

The housing 90 includes a protruding portion 92 that protrudes downward from the facing surface 93 toward the rotary table 2. The protruding portion 92 encircles the perimeter of the third plasma processing region P3 that is below the housing 90. The third process gas nozzles 33 to 36 are disposed in the plasma processing region P3 that is defined by the facing surface 93 in the housing 90, the inner peripheral surface of the protruding portion 92, and the upper surface of the rotary table 2. The protruding portion 92, which is located at the bases (on an inner wall side of the processing chamber 1) of the third process gas nozzles 33 to 36, is cut out to have a substantially arc shape that corresponds to the outer shapes of the third process gas nozzles 33 to 36.

The third process gas is delivered via the third process gas nozzles 33 to 36, in response to the operation of the plasma source 80. With this arrangement, the plasma is formed in the plasma processing region P3. A gas mixture MG of (i) a noble gas for plasma formation and (ii) an additive gas containing one or more among ammonia (NH₃), oxygen (O₂), hydrogen (H₂), and the like for improvement of film quality is delivered via the third process gas nozzles 33 to 35, and further a noble gas (hereinafter referred to as a single noble gas RG) that is not mixed with any additive gas is delivered via the third process gas nozzle 36. An example of the noble gas used for plasma formation includes Ar gas or He gas. In the following, a case of using the Ar gas is described.

Specifically, the third process gas nozzles 33 to 36 include a base nozzle 33, an outer nozzle 34, an axis-side nozzle 35, and a noble gas nozzle 36. In this case, the gas mixture MG is delivered via each of the base nozzle 33, the outer nozzle 34, and the axis-side nozzle 35, and the single noble gas RG is delivered via the noble gas nozzle 36. It is sufficient when the substrate processing apparatus 100 does not include one or both of the outer nozzle 34 and the axis-side nozzle 35.

As illustrated in FIGS. 3 to 5, the base nozzle 33 is a gas nozzle via which the gas mixture MG is supplied onto the entire surface of the wafer W. The base nozzle 33 is disposed upstream (near the protruding portion 92) of the plasma processing region P3 with respect to the rotation direction of the rotary table 2. The base nozzle 33 linearly extends in the radial direction of the rotary table 2, such that an end of the base nozzle 33 is disposed proximal to the central region C of the processing chamber 1. A first gas mixture MG1 of Ar gas, NH₃ gas, O₂ gas, and H₂ gas is delivered via the base nozzle 33.

For example, the base nozzle 33 is disposed at a location (vertical upper side) closer to the facing surface 93 than the outer nozzle 34 and the axis-side nozzle 35 are. The base nozzle 33, the outer nozzle 34, and the axis-side nozzle 35 may be disposed on the same level. Alternately, the outer nozzle 34 and the axis-side nozzle 35 may be vertically disposed above the base nozzle 33. Although FIG. 3 illustrates a state in which the axis-side nozzle 35 is vertically disposed above the outer nozzle 34, the height of the outer nozzle 34 and the height of the axis-side nozzle 35 may be matched. Alternatively, the axis-side nozzle 35 may be vertically disposed below the outer nozzle 34.

The base nozzle 33 has gas holes 33a that are directed to a downstream side with respect to the rotation direction of the rotary table 2. The gas holes 33a are arranged at regular intervals in the longitudinal direction of the base nozzle 33 so as to correspond to the installation location (below the facing surface 93) of the plasma source 80. The first gas mixture MG1 is delivered through the gas holes 33a so as to flow in a direction parallel to a planar direction (horizontal direction) of the facing surface 93 in the housing 90. The gas holes 33a may be formed to be inclined obliquely and downwardly (rotary table 2-side) relative to the horizontal direction, such that the first gas mixture MG1 is delivered toward the rotary table 2.

The outer nozzle 34 is a nozzle for mainly supplying the gas mixture MG onto the outer region of the wafer W, and is proximally provided upstream in the plasma processing region P3 with respect to the rotation direction of the rotary table 2. The outer nozzle 34 includes (i) a radial portion that radially extends a short distance from an outer peripheral wall of the processing chamber 1 toward the central region C and (ii) an outer portion that is obtained by bending the radial portion near the outer peripheral wall, the outer portion extending linearly in a clockwise direction. The outer portion of the outer nozzle 34 has one or more gas holes 34a. For example, the gas holes 34a include (i) one or more holes that face the central region C and (ii) one or more holes that are directed obliquely downwardly (rotary table 2-side).

The axial-side nozzle 35 is a nozzle for mainly supplying the gas mixture MG onto the wafer W that is in proximity to the central region C of the processing chamber 1. The axis-side nozzle 35 is proximally provided downstream in the plasma processing region P3 with respect to the rotation direction of the rotary table 2. The axis-side nozzle 35 includes (i) a radial portion that radially extends from the outer peripheral wall of the processing chamber 1 toward the central region C and (ii) an axial-side portion that is obtained by bending the radial portion near the outer peripheral wall, the axis-side portion extending linearly in a counterclockwise direction (direction opposite the rotation direction of the rotary table 2). The axis-side portion of the axis-side nozzle 35 has one or more gas holes 35a. For example, the gas holes 35a includes (i) one or more holes that face the outer peripheral wall of the processing chamber 1 and (ii) one or more holes that are directed obliquely downwardly (rotary table 2-side).

Unlike the first gas mixture MG1 (Ar gas, NH₃ gas, O₂ gas, and H₂ gas) supplied via the base nozzle 33, the second gas mixture MG2 of Ar gas and NH₃ gas is delivered via each of the outer nozzle 34 and the axis-side nozzle 35. The same gas mixture MG may be delivered via the base nozzle 33, the outer nozzle 34, and the axis-side nozzle 35.

The noble gas nozzle 36 is a gas nozzle via which the single noble gas RG is supplied to flow along the facing surface 93. The noble gas nozzle 36 is disposed at a location closer to the facing surface 93 (vertical upper side) than the base nozzle 33 is. The noble gas nozzle 36 and the base nozzle 33 extend parallel to each other to be along the planar direction of the surface 93. In addition, the noble gas nozzle 36 has substantially the same extension length as the base nozzle 33. The noble gas nozzle 36 may be disposed without contacting the facing surface 93, or may be disposed to extend in contact with the facing surface 93.

As illustrated in FIGS. 4 and 5, the noble gas nozzle 36 and the base nozzle 33 are arranged at locations close to each other. For example, a distance between the base nozzle 33 and the noble gas nozzle 36 is set to be shorter than the diameters of these nozzles. In a plan view, the noble gas nozzle 36 according to the present embodiment is disposed further downstream of the base nozzle 33 in the plasma processing region P3, with respect to the rotation direction of the rotary table 2. However, the noble gas nozzle 36 may be disposed further upstream of the base nozzle 33 with respect to the rotation direction of the rotary table 2, or may be disposed to overlap with the base nozzle 33 in a plan view. The noble gas nozzle 36 and the base nozzle 33 may be formed by one tube with respective flow paths of the gas mixture MG and the single noble gas RG.

The noble gas nozzle 36 has gas holes 36a that are directed to a downstream side with respect to the rotation direction of the rotary table 2. The gas holes 36a are arranged at regular intervals in the longitudinal direction of the noble gas nozzle 36 so as to correspond to the installation location of the plasma source 80 (below the facing surface 93). The single noble gas RG is delivered through the gas holes 36a to flow in a direction parallel to the planar direction (horizontal direction) of the facing surface 93 of the plasma source 80. The gas holes 36a may be formed to be inclined obliquely upwardly (toward the facing surface 93) relative to the horizontal direction. Each gas hole 36a may be formed as an elongated hole that is along the longitudinal direction of the noble gas nozzle 36, in order to form a laminar flow of the single noble gas RG, along the planar direction of the facing surface 93.

By delivering the single noble gas RG through the gas holes 36a of the noble gas nozzle 36, the single noble gas RG can flow along the facing surface 93. With this arrangement, a flow layer of the single noble gas RG is formed in proximity to the facing surface 93, and thus the gas mixture MG is restricted from flowing toward the facing surface 93. The number of noble gas nozzles 36 that are provided in the plasma processing region P3 is not limited to one, and may be plural.

The third process gas nozzles 33 to 36 are coupled to the process gas supply 37 outside the processing chamber 1. In order to supply the third process gas, the process gas supply 37 includes an Ar gas source 371, a NH₃ gas source 372, a O₂ gas source 373, a H₂ gas source 374, a first mixing unit 375a, and a second mixing unit 375b. Each of the first mixing unit 375a and the second mixing unit 375b generates a given gas mixture MG. A type of additive gas that is mixed by the process gas supply 37 is not particularly limiting. The additive gas may include one or two among NH₃ gas, O₂ gas, and H₂ gas. Alternatively, any other additive gas (for example, N₂ gas) may be mixed.

The first mixing unit 375a is a buffer that generates the first gas mixture MG1 of Ar gas, NH₃ gas, O₂ gas, and H₂ gas. The second mixing unit 375b is a buffer that generates the second gas mixture MG2 of Ar gas and NH₃ gas. A flow rate regulator (not illustrated), an opening-and-closing valve (not illustrated), and the like are provided between the first mixing unit 375a and one among the Ar gas source 371, the NH₃ gas source 372, the 02 gas source 373, and the H₂ gas source 374. Likewise, a flow rate regulator (not illustrated), an opening-and-closing valve (not illustrated), and the like are provided between the second mixing unit 375b and one among the Ar gas source 371, the NH₃ gas source 372, the O₂ gas source 373, and the H₂ gas source 374. As in a mixture proportion of the second gas mixture MG2, the process gas supply 37 can adjust a mixture proportion of the first gas mixture MG1 when at least one flow rate regulator regulates a flow rate of the gas supplied by a corresponding gas source.

The base nozzle 33 is coupled to the second mixing unit 375b via a first gas-mixture path 376. A flow rate regulator 376a, an opening-and-closing valve 376b, and the like are provided at intermediate locations of the first gas-mixture path 376. Under the control of the controller 110, in the process gas supply 37, the opening-and-closing valve 376b is opened and closed to switch between supply and termination of the supply of the second gas mixture MG2 to the base nozzle 33. Also, under the control of the controller 110, the flow rate regulator 376a regulates the flow rate of the second gas mixture MG2.

The outer nozzle 34 is coupled to the first mixing unit 375a via a second gas-mixture path 377. A flow rate regulator 377a, an opening-and-closing valve 377b, and the like are provided at intermediate locations of the second gas-mixture path 377. Under the control of the controller 110, in the process gas supply 37, the opening-and-closing valve 377b is opened and closed to switch between supply and termination of the supply of the first gas mixture MG1 to the outer nozzle 34. Also, under the control of the controller 110, the flow rate regulator 377a regulates the flow rate of the first gas mixture MG1.

Likewise, the axis-side nozzle 35 is coupled to the first mixing unit 375a via a third gas-mixture path 378. A flow rate regulator 378a, an opening-and-closing valve 378b, and the like are provided at intermediate locations of the third gas-mixture path 378. Under the control of the controller 110, in the process gas supply 37, the opening-and-closing valve 378b is opened and closed to switch between supply and termination of the supply of the first gas mixture MG1 to the axis-side nozzle 35. Also, under the control of the controller 110, the flow rate regulator 378a regulates the flow rate of the first gas mixture MG1.

The noble gas nozzle 36 is coupled to the Ar gas source 371 via a single gas path 379. A flow rate regulator 379a, an opening-and-closing valve 379b, and the like are provided at intermediate locations of the single gas path 379. Under the control of the controller 110, in the process gas supply 37, the opening-and-closing valve 379b is opened and closed to switch between supply and termination of the supply of the single noble gas RG to the noble gas nozzle 36. Also, under the control of the controller 110, the opening-and-closing valve 379b regulates the flow rate of the single noble gas RG.

The basic configuration of the substrate processing apparatus 100 according to the present embodiment is as described above. The operation (method for processing a substrate) of the substrate processing apparatus 100 will be described below.

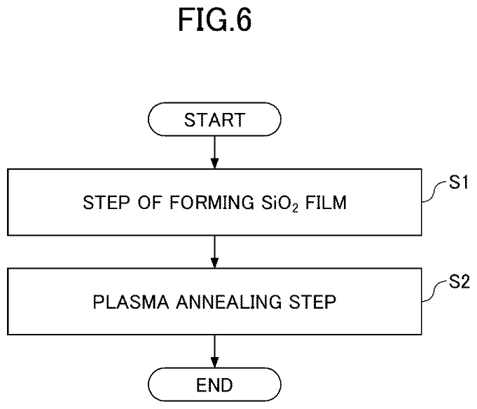

FIG. 6 is a flowchart illustrating an example of the method for processing the substrate. After a given wafer W is placed in each recess 24 of the rotary table 2 in the processing chamber 1, the controller 110 of the substrate processing apparatus 100 executes the method for processing the substrate in which a step S1 of forming a SiO₂ film and a plasma annealing step S2 are sequentially performed as illustrated in FIG. 6.

In the step S1 of forming the SiO₂ film, in a state where the pressure regulator 64 and a vacuum-exhausting mechanism 65 adjust the pressure in the processing chamber 1 to a predetermined pressure, the controller 110 causes the heater unit 7 to heat the wafer W at a predetermined temperature, while rotating the rotary table 2. In this case, the controller 110 causes separation gas (for example, Ar gas) to be supplied via the separation gas nozzles 41 and 42.

The controller 110 also causes a silicon-containing gas, which is a first process gas, to be supplied via the first process gas nozzle 31. Thus, the silicon-containing gas adheres to the surface of the wafer W in the first processing region P1.

The controller 110 further causes an oxidation gas, which is a second process gas, to be supplied via the second process gas nozzle 32. With this arrangement, in the second processing region P2, the silicon-containing gas that is on the wafer W and is moved in accordance with the rotation of the rotary table 2 is oxidized by the oxidization gas. Thus, a molecular layer of SiO₂ that is a thin film component is formed and deposited on the wafer W.

The controller 110 continues the rotation of the rotary table 2 to repeat a cycle in which (i) the silicon-containing gas adheres to the surface of the wafer W and (ii) a silicon-containing gas component oxidizes. As a result, a SiO₂ film having a desired thickness is deposited on the surface of the wafer W. When the thickness of the SiO₂ film becomes a desired thickness, the controller 110 terminates the step S1 of forming the SiO₂ film.

In the plasma annealing step S2, in a state in which the pressure regulator 64 and the vacuum-exhausting mechanism 65 adjust the pressure in the processing chamber 1 to a predetermined pressure, the controller 110 causes the heater unit 7 to heat the wafer W at a predetermined temperature, while the controller rotates the rotary table 2. In this case, the controller 110 causes separation gas (for example, Ar gas) to be supplied via the separation gas nozzles 41 and 42.

Then, the controller 110 controls the process gas supply 37 to cause the first gas mixture MG1 (Ar gas, NH₃ gas, O₂ gas, and H₂ gas) to be delivered via the base nozzle 33. The controller 110 also controls the process gas supply 37 to cause the second gas mixture MG2 (Ar gas and NH₃ gas) to be delivered via the outer nozzle 34 and the axis-side nozzle 35. Further, the controller 110 controls the process gas supply 37 to cause the single noble gas RG to be delivered via the noble gas nozzle 36. In such a state, the controller 110 causes RF power to be supplied by the RF power source 85 to the antenna 83. Thus, induced electric fields are generated in the plasma processing region P3.

In the plasma processing region P3, the Ar gas is excited by the radio frequency wave to form a plasma. In addition, the O₂ gas improves oxidization of silicon. The H₂ gas forms OH groups on the surface of the wafer W. In particular, by a plasma condition, the H₂ gas creates the distribution of the OH groups with respect to a depth direction of one or more trenches in the wafer W. Also, by using a difference between adsorption amounts, filling characteristics for each trench having a V-shape can be improved. In addition, the NH₃ gas improves filling characteristics for the surface of the wafer W with the trenches.

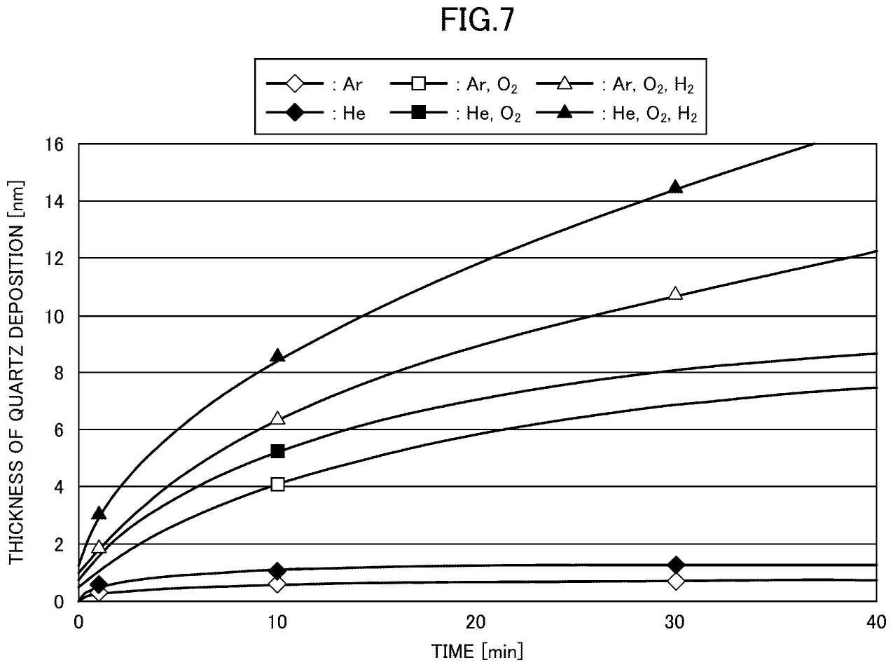

FIG. 7 is a graph illustrating a deposited amount of quartz in a test in which plasma processing was performed in the substrate processing apparatus 100. On the graph, the horizontal axis represents the processing time [min], and the vertical axis represents the thickness [nm] of quartz deposition that was generated by the plasma processing. In this test, as a process condition, a given wafer W was heated to 400° C., the pressure in the processing chamber 1 was adjusted to be within the range of 1.8 Torr (240 Pa) to 2.0 Torr (267 Pa), and radio frequency power of 4000 W was supplied to the antenna 83.

As seen from the test result illustrated in FIG. 7, when Ar gas or He gas, which is a noble gas, is singly supplied, the thickness of the quartz deposition is reduced. That is, it can be seen that the quartz deposition (particles) is not appreciably generated in a case where only the Ar gas or He gas that is a plasma gas is supplied. This is because, even if quartz that constitutes the housing 90 is physically bombarded with the Ar gas or He gas from which the plasma is formed, the quartz is not damaged by the physical bombardment.

In contrast, compared to a case where Ar gas or He gas is singly supplied, the thickness of quartz deposition is increased in a case where each of (i) O₂ gas and H₂ gas are added to He gas, (ii) 02 gas is added to He gas, (iii) O₂ gas and H₂ gas are added to Ar gas, and (iv) O₂ gas is added to Ar gas. This results from the fact that the O₂ gas or the H₂ gas, from which the plasma is formed, chemically reacts with the Ar gas and the He gas, so that the quartz surface is etched. Thus, the quartz surface is further damaged in accordance with an increasing time period in which plasma processing is performed.

In the substrate processing apparatus 100 according to the present embodiment, the single noble gas RG (only Ar gas) is delivered at a location closer to the facing surface 93 than the first gas mixture MG1 (Ar gas, NH₃ gas, O₂ gas, and H₂ gas) and the second gas mixture MG2 (Ar gas and NH₃ gas) are delivered. That is, as illustrated in FIGS. 4 and 5, a given gas mixture MG is delivered via the base nozzle 33 (as in the outer nozzle 34 and the axis-side nozzle 35) to flow horizontally or toward the rotary table 2, while the single noble gas RG is delivered via the noble gas nozzle 36 to flow horizontally along the facing surface 93.

In such a manner, in the plasma processing region P3, the flow layer of a given gas mixture MG is formed toward the rotary table 2, and the flow layer of the single noble gas RG is formed closer to the facing surface 93 than the flow layer of the gas mixture MG is. Thus, in the substrate processing apparatus 100, because the quartz surface comes into contact with only the plasma that is formed from the Ar gas, damage due to the chemical reaction between the quartz of the facing surface 93 and the additive gas (NH₃ gas, H₂ gas, and O₂ gas) is avoided. In addition, NH₃ gas, H₂ gas, O₂ gas, and the like, below the flow layer of the single noble gas RG, are excited by applying the plasma that is formed from the excited Ar gas. As a result, the substrate processing apparatus 100 can reduce damage to the quartz to suppress generation of quartz particles, as well as improving filling characteristics by using NH₃. In addition, because damage to the quartz is significantly suppressed, a use period of the processing chamber 1 (housing 90) can be increased.

In the plasma processing, the controller 110 can control the process gas supply 37 to appropriately adjust (i) a timing of the gas mixture MG that is delivered via each of the base nozzle 33, the outer nozzle 34, and the axis-side nozzle 35 and (ii) a timing of the single noble gas RG that is delivered via the noble gas nozzle 36. For example, the controller 110 sets a timing at which each gas mixture MG is delivered to be aligned with a timing at which the single noble gas RG is delivered, and causes the noble gas to be continuously delivered during a period in which a given gas mixture MG is delivered. Alternatively, the controller 110 may cause a given gas mixture MG to be delivered after the single noble gas RG is first delivered. With this arrangement, in the plasma processing region P3, a given gas mixture MG is supplied in a state where the flow layer of the single noble gas RG is formed proximal to the facing surface 93. Thus, damage to the facing surface 93 can be suppressed more reliably.

Further, the controller 110 can control the process gas supply 37 to appropriately adjust a delivered amount of a given gas mixture MG and a delivered amount of the single noble gas RG. For example, the controller 110 adjusts an amount of the single noble gas RG that is delivered via the noble gas nozzle 36 to be larger than an amount of the gas mixture MG that is delivered via the base nozzle 33. With this arrangement, the gas mixture MG can be more reliably inhibited from flowing toward the facing surface 93. A ratio of the amount of the delivered single noble gas RG to the amount of a delivered given gas mixture MG may be approximately in the range of 1.1 times to 2.0 times, for example.

A ratio of a total amount of additive gas to a total amount of Ar gas that is supplied to the plasma processing region P3 is set to about 1%. In the substrate processing apparatus 100, by supplying a larger amount of the single noble gas RG from the noble gas nozzle 36, a mixture proportion of the additive gas in the gas mixture MG, which is supplied from a corresponding one among the base nozzle 33, the outer nozzle 34, and the axis-side nozzle 35 that are situated below the noble gas nozzle 36, can be increased in comparison to conventional mixture proportions. With this arrangement, in the substrate processing apparatus 100, efficiency in performing plasma processing and improvement of film quality can be increased. The controller 110 may set the amount of the delivered single noble gas RG to be smaller than the amount of a delivered given gas mixture MG, in order to form a laminar flow of the single noble gas RG across the entire facing surface 93.

When the plasma annealing step S2 is terminated, the controller 110 of the substrate processing apparatus 100 controls the process gas supply 37 to stop supplying the third process gas, and stops supplying the radio frequency power to the plasma source 80. Thereafter, the controller 110 causes a processed wafer W to be transferred out of the processing chamber 1, and then terminates the process. In the method for processing the substrate according to the above embodiment, the step S1 of forming the SiO₂ film and the plasma annealing step S2 are sequentially performed once. However, a number of times that these steps are performed is not limiting, and the step S1 of forming the SiO₂ film and the plasma annealing step S2 may be alternately repeated a plurality of times.

In the present disclosure, the substrate processing apparatus 100 and a method for processing the substrate are not limited to the above-described embodiments, and various modifications can be made. For example, the noble gas nozzle 36 is not limited to a linear tube that is parallel to the base nozzle 33, and may take various aspects. As an example, the noble gas nozzle 36 may be configured to have an annular tube that encircles the perimeter of the antenna 83, such that a single noble gas is delivered into the annular tube.

### Second Embodiment

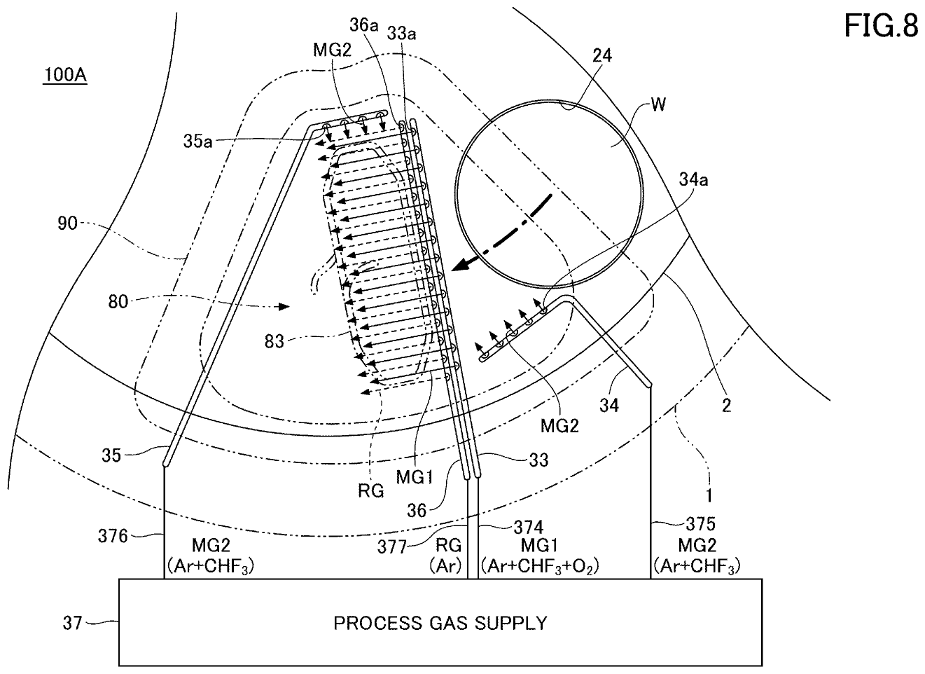

FIG. 8 is a schematic plan view of the plasma processing region P3 of a substrate processing apparatus 100A according to the second embodiment. As illustrated in FIG. 8, the substrate processing apparatus 100A according to the second embodiment differs from the substrate processing apparatus 100 (film deposition apparatus) according to the above-described embodiment, in that the substrate processing apparatus 100A etches a film (e.g., SiO₂ film) that is formed in a given wafer W in the plasma processing region P3. For example, in the substrate processing apparatus 100A, a third process gas including (i) Ar gas that is a plasma gas and (ii) trifluoromethane (CHF₃) gas and O₂ gas that are additive gases, is delivered to the plasma processing region P3. An etching process gas is not limited to the CHF₃ gas, and any appropriate gas may be employed depending on the type of a film that is formed in the wafer W.

In the substrate processing apparatus 100A, a given gas mixture MG is delivered via each of the base nozzle 33, the outer nozzle 34, and the axis-side nozzle 35, and the single noble gas RG is delivered via the noble gas nozzle 36. More specifically, in the substrate processing apparatus 100A, a first gas mixture MG1 of the Ar gas, the CHF₃ gas, and the O₂ gas is delivered via the base nozzle 33. Also, in the substrate processing apparatus 100A, a second gas mixture MG2 of the Ar gas and the CHF₃ gas is delivered via the outer nozzle 34 and the axis-side nozzle 35. In addition, in the substrate processing apparatus 100A, the single noble gas RG that contains only Ar gas is delivered via the noble gas nozzle 36.

As described above, even in the substrate processing apparatus 100A that performs an etch process, damage to the facing surface 93 can be suppressed by injecting the single noble gas RG to a location near the facing surface 93. That is, in the substrate processing apparatus 100A, a given flow layer of only Ar gas is formed proximal to the facing surface 93, and thus damage due to the chemical reaction between quartz, which constitutes the facing surface 93, and additive gas (CHF₃ gas and O₂ gas) can be reduced. Also, the CHF₃ gas, the O₂ gas, and the like are excited by a plasma formed from the excited Ar gas, below a given flow layer of the single noble gas RG. With this arrangement, in the substrate processing apparatus 100A, damage to a quartz surface can be reduced, while improving an etch characteristic for the CHF₃ gas. Thus, a use period for the housing 90 can be increased.

The technical concept and effect of the present disclosure, as illustrated in the above embodiments, are described below.

A first aspect of the present disclosure relates to the substrate processing apparatuses 100 and 100A. Each of the substrate processing apparatuses 100 and 100A includes a processing chamber 1 configured to process a substrate (wafer W). Each of the substrate processing apparatuses 100 and 100A includes a substrate support (rotary table 2) provided in the processing chamber 1 and configured to support the substrate. Each of the substrate processing apparatuses 100 and 100A includes a plasma source 80 configured to generate an electric field in a plasma processing region P3 between a surface 93 facing the substrate support and the substrate support, the electric field causing formation of a plasma. Each of the substrate processing apparatuses 100 and 100A includes process gas nozzles (third process gas nozzles 33 to 36) via which a gas is delivered to the plasma processing region P3. The process gas nozzles include a gas mixture nozzle (base nozzle 33) via which a gas mixture MG of additive gas and a noble gas for forming the plasma is delivered. The process gas nozzles include a noble gas nozzle 36 via which the noble gas, which is not mixed with the additive gas, is delivered to flow along the facing surface 93, the noble gas nozzle 36 being provided at a location closer to the facing surface 93 than the gas mixture nozzle is.

With this arrangement, during formation of the plasma, each of the substrate processing apparatuses 100 and 100A can reduce damage to the processing chamber 1 by delivering the noble gas via the noble gas nozzle 36 to be along the facing surface 93. That is, a flow layer of the noble gas that flows along the facing surface 93 prevents the additive gas from moving to the facing surface 93. Thus, chemical reactions between the facing surface 93 and the additive gas are suppressed. Accordingly, in each of the substrate processing apparatuses 100 and 100A, generation of particles due to damage to the processing chamber 1 can be reduced as much as possible, as well as increasing durability of the processing chamber 1.

The noble gas nozzle 36 has a gas hole 36a through which a noble gas is delivered in a direction parallel to the facing surface 36a. With this arrangement, in each of the substrate processing apparatuses 100 and 100A, a flow layer of the noble gas can be appropriately formed to be along the facing surface 93.

A gas mixture nozzle (base nozzle 33) and the noble gas nozzle 36 extend in parallel to each other to be along a planar direction of the facing surface 93. With this arrangement, in each of the substrate processing apparatuses 100 and 100A, an area in which a gas mixture MG is delivered via the gas mixture nozzle can be covered with a flow layer of a noble gas that is delivered via the noble gas nozzle. Thus, damage to the facing surface 93 can be more reliably reduced.

A flow rate of a noble gas that is delivered via the noble gas nozzle 36 is greater than a flow rate of a gas mixture MG that is delivered via a gas mixture nozzle (base nozzle 33). With this arrangement, each of the substrate processing apparatuses 100 and 100A can further suppress movement of the gas mixture MG to the facing surface 93, by the noble gas delivered via the noble gas nozzle 36.

Each substrate processing apparatus further includes a controller 110 configured to control delivery of the gas from each of process gas nozzles (third process gas nozzles 33 to 36). The controller 110 sets a first timing at which a noble gas is delivered via a noble gas nozzle 36 to be before a second timing at which a gas mixture MG is delivered via a gas mixture nozzle (base nozzle 33). The controller also causes the noble gas to be continuously delivered via the noble gas nozzle 36 during a period in which the gas mixture MG is delivered via the gas mixture nozzle. With this arrangement, each of the substrate processing apparatuses 100 and 100A can constantly generate a flow layer of the noble gas on the facing surface 93, during delivery of the gas mixture MG. Thus, the facing surface 93 can be protected.

A noble gas is argon gas or helium gas. In this case, each of the substrate processing apparatuses 100 and 100A can stably form a plasma. Also, even when the facing surface 93 is bombarded with the plasma, damage to the facing surface 93 can be suppressed.

Additive gas includes at least one of ammonia gas, oxygen gas, or hydrogen gas. In this case, each of the substrate processing apparatuses 100 and 100A can appropriately perform plasma processing of a wafer W while the facing surface 93 is covered with a noble gas.

Additive gas includes an etch gas for a film of a substrate. In this case, the substrate processing apparatus 100A can suppress damage to the processing chamber 1 even in a case where the film of a wafer W is etched in substrate processing.

The facing surface 93 of the plasma source 80 is formed of quartz. With this arrangement, even when the facing surface 93 is physically bombarded with a given noble gas from which the plasma is formed, occurrence of damage to the facing surface 93 can be reduced. Also, chemical reactions with additive gas are interrupted by a flow layer of the noble gas. Thus, in each of the substrate processing apparatuses 100 and 100A, the plasma source 80 can be stably used for a long time period.

A substrate support includes recesses 24 in which respective substrates (wafers W) are accommodated in a processing chamber 1. The substrate support includes a rotary table 2 configured to revolve the respective substrates accommodated in the recesses. The processing chamber 1 includes a plasma source 80 above a region where the recesses 24 pass. The processing chamber 1 includes a gas mixture nozzle (base nozzle 33) and a noble gas nozzle 36. With this arrangement, each of the substrate processing apparatuses 100 and 100A can effectively suppress damage to the processing chamber 1 even when the plasma is formed using an apparatus that revolves one or more substrates.

A second aspect of the present disclosure relates to a method for processing a substrate (wafer W) by a substrate processing apparatus. The substrate processing apparatus includes (i) a processing chamber 1 configured to house the substrate, (ii) a substrate support (rotary table 2) provided in the processing chamber 1 and configured to support the substrate, (iii) a plasma source 80 configured to generate an electric field in a plasma processing region P3 between a surface 93 facing the substrate support and the substrate support, the electric field causing formation of a plasma, and (iv) process gas nozzles (third process gas nozzles 33 to 36) via which a gas is delivered to the plasma processing region P3. The method includes delivering, via a gas mixture nozzle (base nozzle 33) that is a given process gas nozzle among the process gas nozzles, a gas mixture MG of additive gas and a noble gas for forming the plasma. The method includes delivering, via a noble gas nozzle 36 that is a given process gas nozzle among the process gas nozzles, the noble gas that is not mixed with the additive gas, the delivered noble gas flowing along the facing surface 93, and the noble gas nozzle 36 being provided at a location closer to the facing surface 93 than the gas mixture nozzle is. The method includes forming the plasma through the plasma source 80. In this case, damage to the processing chamber can be reduced during formation of the plasma.

While certain embodiments are described using the substrate processing apparatuses 100 and 100A and a method for processing a substrate, these embodiments are presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the scope of the disclosures. The accompanying claims and their equivalents are intended to cover such forms or modifications as would fall within the scope of the disclosures.

For example, each of the substrate processing apparatuses 100 and 100A may have a structure that does not rotate a substrate support for supporting one or more wafers W. Alternatively, in the structure of each of the substrate processing apparatuses 100 and 100A, the substrate support may rotate about a central axis of one wafer W. Also, the substrate processing apparatus 100 may have a structure in which each of wafers W rotates around the central axis of the wafer while the wafers W revolve in an orbital motion.

According to one aspect, damage to a processing chamber can be reduced during formation of a plasma.

What is claimed is:

1. A substrate processing apparatus comprising:
a processing chamber configured to process a substrate;
a substrate support provided in the processing chamber and configured to support a substrate;
a plasma source configured to generate an electric field in a plasma processing region between a surface facing the substrate support and the substrate support, the electric field causing formation of a plasma; and
process gas nozzles via which a gas is delivered to the plasma processing region, the process gas nozzles including
a gas mixture nozzle via which a gas mixture of an additive gas and a noble gas for forming the plasma is delivered, and
a noble gas nozzle via which the noble gas, which is not mixed with the additive gas, is delivered to flow along the facing surface, the noble gas nozzle being provided at a location closer to the facing surface than the gas mixture nozzle is.

2. The substrate processing apparatus according to claim 1, wherein the noble gas nozzle has a gas hole through which the noble gas is delivered in a direction parallel to the facing surface.

3. The substrate processing apparatus according to claim 2, wherein the gas mixture nozzle and the noble gas nozzle extend in parallel to each other to be along a planar direction of the facing surface.

4. The substrate processing apparatus according to claim 1, wherein a flow rate of the noble gas that is delivered via the noble gas nozzle is greater than a flow rate of the gas mixture that is delivered via the gas mixture nozzle.

5. The substrate processing apparatus according to claim 1, further comprising a controller, the controller being configured to
control delivery of the gas from each of the process gas nozzles,
set a first timing at which the noble gas is delivered via the noble gas nozzle to be before a second timing at which the gas mixture is delivered via the gas mixture nozzle, and
cause the noble gas to be continuously delivered via the noble gas nozzle during a period in which the gas mixture is delivered via the gas mixture nozzle.

6. The substrate processing apparatus according to claim 1, wherein the noble gas includes argon gas or helium gas.

7. The substrate processing apparatus according to claim 1, wherein the additive gas includes at least one of ammonia gas, oxygen gas, or hydrogen gas.

8. The substrate processing apparatus according to claim 1, wherein the additive gas includes an etch gas for a film of the substrate.

9. The substrate processing apparatus according to claim 1, wherein the facing surface in the plasma source is formed of quartz.

10. The substrate processing apparatus according to claim 1,
wherein the substrate support includes
recesses in which respective substrates are accommodated in the processing chamber, and
a rotary table configured to revolve the respective substrates accommodated in the recesses, and
wherein the processing chamber includes
the plasma source above a region where the recesses pass,
the gas mixture nozzle, and
the noble gas nozzle.

11. A method for processing a substrate by a substrate processing apparatus, the substrate processing apparatus including
a processing chamber configured to accommodate the substrate,
a substrate support provided in the processing chamber and configured to support the substrate,
a plasma source configured to generate an electric field in a plasma processing region between a surface facing the substrate support and the substrate support, the electric field causing formation of a plasma, and
process gas nozzles via which a gas is delivered to the plasma processing region, the method comprising:
delivering, via a gas mixture nozzle that is a given process gas nozzle among the process gas nozzles, a gas mixture of an additive gas and a noble gas for forming the plasma;
delivering, via a noble gas nozzle that is a given process gas nozzle among the process gas nozzles, the noble gas that is not mixed with the additive gas, the delivered noble gas flowing along the facing surface, and the noble gas nozzle being provided at a location closer to the facing surface than the gas mixture nozzle is; and
forming the plasma through the plasma source.
